(19) United States
(12) Patent Application Publication
(10) Pub. No.: US 2024/0052237 A1
(43) Pub. Date: Feb. 15, 2024

(54) COMPOSITE MATERIAL AND PREPARATION METHOD THEREFOR, AND QUANTUM DOT LIGHT-EMITTING DIODE AND PREPARATION METHOD THEREFOR

(71) Applicant: TCL TECHNOLOGY GROUP CORPORATION, Huizhou, Guangdong (CN)

(72) Inventors: Sina HE, Huizhou, Guangdong (CN); Longjia WU, Huizhou, Guangdong (CN); Jingheng WU, Huizhou, Guangdong (CN)

(73) Assignee: TCL TECHNOLOGY GROUP CORPORATION, Huizhou, Guangdong (CN)

(21) Appl. No.: 18/260,476

(22) PCT Filed: Dec. 31, 2021
(86) PCT No.: PCT/CN2021/143615

§ 371 Date: Jul. 6, 2023

(30) Foreign Application Priority Data
Apr. 28, 2021 (CN) 202110467604.7

(51) Int. Cl. C09K 11/02; C09K 11/56; H10K 50/115

(52) U.S. Cl. CPC C09K 11/025; C09K 11/565; H10K 50/115; B82Y 20/00

(57) ABSTRACT

The present application provides a composite material and a preparation method therefor, and a quantum dot light-emitting diode and a preparation method therefor, which relate to the field of display. The composite material comprises quantum dots and MXenes, metal atoms of the quantum dots are linked to surface groups of the MXenes by means of coordination bonds. An application of the composite material of the present application in a quantum dot light-emitting diode can increase the carrier injection speed and improve the performance of the quantum dot light-emitting diode.

The present application claims priority to Chinese Patent Application No. 202110467604.7, filed on Apr. 28, 2021, and entitled “composite material and preparation method therefor, and quantum dot light-emitting diode and preparation method therefor”, the disclosure of which is incorporated herein by reference in its entirety.

### TECHNICAL FIELD

The present disclosure relates to the field of display, and in particular, to a composite material and a preparation method therefor, and a quantum dot light-emitting diode and a preparation method therefor.

### BACKGROUND

Nowadays, the mainstream display technology is LCD display technology, which requires the use of a backlight, but the existing backlight technology has many limitations such as high power consumption, complex structure and process, and high cost. In order to improve these problems, quantum dots with excellent optical properties, such as continuously adjustable full-spectrum emission peak positions, high color purity, good stability, have been applied to backlight technology.

The color gamut of a display screen can be significantly improved in case that conventional phosphors are replaced by quantum dots. Application of quantum dots in backlight modules have shown that the color gamut of a display screen can be improved from 72% NTSC to 110% NTSC. In addition, when quantum dots get rid of the backlight technology and are applied to an active matrix quantum dot light-emitting diode display device, a self-emitting quantum dot light-emitting diode has more prominent display effect in a scene such as a black expression and a high brightness conditions, lower power consumption, wider adaptable temperature range compared with a conventional backlight LCD, so it can be used to prepare a display screen with a color gamut of up to 130% NTSC.

Quantum dot light-emitting diode have good performance in all aspects, but their device efficiency, device working stability and other parameters still have a certain gap with the requirements of industrial application. Especially, the surface of the quantum dots commonly used in the display field is usually coated with a long carbon chain of oleic acid, which hinders the movement of carriers, and leads to a low transport capacity of carriers in quantum dot light-emitting diodes. Accordingly, there is a need for an effective method to address the above problems.

### Technical Problems

The present disclosure provides a composite material and a preparation method therefor, and a quantum dot light-emitting diode and a preparation method therefor, which can improve the problems of low carrier transport capacity and limited application of quantum dots in optoelectronic devices in the existing quantum dot light-emitting diodes.

### Technical Solutions

The present disclosure provides a composite material including quantum dots and MXenes, wherein metal atoms of the quantum dots are connected to surface groups of the MXenes through coordination bonds.

In some examples, the quantum dots are selected from one or more of CdSe, ZnSe, PbSe, CdTe, InP, GaN, GaP, AlP, InN, ZnTe, InAs, GaAs, CaF₂, Cd₁₋ₓZnₓS, Cd₁₋ₓZnₓSe, CdSe_{y}S_{1-y}, PbSe_{y}S_{1-y}, ZnₓCd₁₋ₓTe, CdS/ZnS, Cd₁₋ₓZnₓS/ZnS, Cd₁₋ₓZnₓSe/ZnSe, CdSe₁₋ₓSₓ/CdSe_{y}S_{1-y}/CdS, CdSe/Cd₁₋ₓZnₓSe/Cd_{y}Zn_{1-y}Se/ZnSe, Cd₁₋ₓZnₓSe/Cd_{y}Zn_{1-y}Se/ZnSe, CdS/Cd₁₋ₓZnₓS/Cd_{y}Zn_{1-y}S/ZnS, NaYF₄, NaCdF₄, Cd₁₋ₓZnₓSe_{y}S_{1-y}, CdSe/ZnS, Cd₁₋ₓZnₓSe/ZnS, CdSe/CdS/ZnS, CdSe/ZnSe/ZnS, Cd₁₋ₓZnₓSe/Cd_{y}Zn_{1-y}S/ZnS, and InP/ZnS; and
wherein, 0≤x≤1, 0≤y≤1, and x and y are not both 0 or 1 at the same time.

In some examples, the quantum dots are quantum dots with core-shell structures, and the metal atom is a shell metal atom of the quantum dots with core-shell structures.

The present disclosure further provides a method for preparing a composite material including steps as follows:
providing a first organic solvent with quantum dots dispersed therein and MXenes;
mixing and reacting the first organic solvent with quantum dots dispersed therein with the MXenes; and
performing solid-liquid separation to obtain the composite material.

In some examples, a molar ratio of the quantum dots to the MXenes is 1:(0.05 to 0.5).

In some examples, a molar ratio of the quantum dots to the MXenes is 1:(0.1 to 0.3).

In some examples, the first organic solvent is an alkene or an alkane with a boiling point ranging from 280° C. to 400° C.

In some examples, a concentration of the quantum dots in the first organic solvent ranges from 20 mg/mL to 50 mg/mL.

In some examples, the mixing and reacting is carried out at a temperature ranging from 200° C. to 250° C. under a protective gas.

In some examples, the mixing and reacting includes mixing the first organic solvent with quantum dots dispersed therein with MXenes and stirring.

In some examples, the stirring is carried out for a time period of from 0.5 h to 1 h.

In some examples, the surface group of the MXenes is selected from one or more of hydroxyl group and halogen groups.

In some examples, the quantum dots are selected from one or more of CdSe, ZnSe, PbSe, CdTe, InP, GaN, GaP, AlP, InN, ZnTe, InAs, GaAs, CaF₂, Cd₁₋ₓZnₓS, Cd₁₋ₓZnₓSe, CdSe_{y}S_{1-y}, PbSe_{y}S_{1-y}, ZnₓCd₁₋ₓTe, CdS/ZnS, Cd₁₋ₓZnₓS/ZnS, Cd₁₋ₓZnₓSe/ZnSe, CdSe₁₋ₓSₓ/CdSe_{y}S_{1-y}/CdS, CdSe/Cd₁₋ₓZnₓSe/Cd_{y}Zn_{1-y}Se/ZnSe, Cd₁₋ₓZnₓSe/Cd_{y}Zn_{1-y}Se/ZnSe, CdS/Cd₁₋ₓZnₓS/Cd_{y}Zn_{1-y}S/ZnS, NaYF₄, NaCdF₄, Cd₁₋ₓZnₓSe_{y}S_{1-y}, CdSe/ZnS, Cd₁₋ₓZnₓSe/ZnS, CdSe/CdS/ZnS, CdSe/ZnSe/ZnS, Cd₁₋ₓZnₓSe/Cd_{y}Zn_{1-y}S/ZnS, and InP/ZnS; and
wherein, 0≤x≤1, 0≤y≤1, and x and y are not both 0 or 1 at the same time.

In some examples, the quantum dots are quantum dots with core-shell structures, and the metal atom is a shell metal atom of the quantum dots with core-shell structures.

The present disclosure further provides a quantum dot light-emitting diode including an anode, a hole transport layer, a light-emitting layer, an electron transport layer, and a cathode that are stacked.

A material of the light-emitting layer includes a composite material.

The composite material includes quantum dots and MXenes, and metal atoms of the quantum dots are connected to surface groups of the MXenes through coordination bonds.

In some examples, the quantum dot light-emitting diode further includes a substrate on which the cathode or the anode is disposed.

In some examples, the surface group of the MXenes is selected from one or more of hydroxyl group and halogen groups.

In some examples, the quantum dots are selected from one or more of CdSe, ZnSe, PbSe, CdTe, InP, GaN, GaP, AlP, InN, ZnTe, InAs, GaAs, CaF₂, Cd₁₋ₓZnₓS, Cd₁₋ₓZnₓSe, CdSe_{y}S_{1-y}, PbSe_{y}S_{1-y}, ZnₓCd₁₋ₓTe, CdS/ZnS, Cd₁₋ₓZnₓS/ZnS, Cd₁₋ₓZnₓSe/ZnSe, CdSe₁₋ₓSₓ/CdSe_{y}S_{1-y}/CdS, CdSe/Cd₁₋ₓZnₓSe/Cd_{y}Zn_{1-y}Se/ZnSe, Cd₁₋ₓZnₓSe/Cd_{y}Zn_{1-y}Se/ZnSe, CdS/Cd₁₋ₓZnₓS/Cd_{y}Zn_{1-y}S/ZnS, NaYF₄, NaCdF₄, Cd₁₋ₓZnₓSe_{y}S_{1-y}, CdSe/ZnS, Cd₁₋ₓZnₓSe/ZnS, CdSe/CdS/ZnS, CdSe/ZnSe/ZnS, Cd₁₋ₓZnₓSe/Cd_{y}Zn_{1-y}S/ZnS, and InP/ZnS; and

wherein, 0≤x≤1, 0≤y≤1, and x and y are not both 0 or 1 at the same time.

In some examples, the quantum dots are quantum dots with core-shell structures, and the metal atom is a shell metal atom of the quantum dots with core-shell structures.

The present disclosure further provides a method for preparing a quantum dot light-emitting diode including steps as follows:
providing a solution in which a composite material is dissolved in a solvent, wherein the solvent is an alkane non-polar solvent;
depositing the solution on an electron transport layer to form a light-emitting layer; or
depositing the solution on a hole transport layer to form a light-emitting layer;
wherein the composite material comprises quantum dots and MXenes, and metal atoms of the quantum dots are connected to surface groups of the MXenes through coordination bonds.

### Advantageous Effects

In the present disclosure, composite materials MXenes-quantum dots are prepared by combining MXenes and quantum dots by the above-described method for preparing composite materials. Since the quantum dots in the composite materials are attached to the two-dimensional MXenes nanosheets, it is possible to improve the agglomeration phenomenon during the film formation process when a light-emitting layer is prepared by the composite materials, so that they have better photostability. Furthermore, when a quantum dot light-emitting diode is prepared by using a light-emitting layer based on the composite materials, fluorescence emission channels are formed between adjacent wrinkled structures of the MXenes nanosheets after the quantum dots in the composite material are attached to the wrinkled structures of the MXenes, so that fluorescence emitted by the quantum dots can be reflected by wrinkled walls and emitted outwardly through the fluorescence emission channels, which can improve the quantum efficiency of the device to some extent. At the same time, electrons are introduced into the light-emitting layer through the electron transport layer, and the light-emitting layer has a good carrier transport capability under the action of the MXenes quantum confinement effect. The carriers are transferred to the quantum dots through the surface groups (such as —OH, —F, or the like) of the Mₙ₊₁XₙT_{z}-type MXenes nanosheets, thereby enhancing the light-emitting efficiency of the device and improving the performance of the quantum dot light-emitting diodes.

### DESCRIPTION OF THE DRAWINGS

In order to explain the technical solutions in examples of the present disclosure more clearly, drawings that need to be used in the description of the examples will be briefly introduced below. Apparently, the accompanying drawings in the following description are only some examples of the present disclosure, but not all the examples of the present disclosure. For those skilled in the art, other drawings can be obtained on the basis of these drawings without any creative work.

FIG. 1 is a flowchart of a method for preparing a composite material according to Example 1 of the present disclosure;

FIG. 2 is a schematic structural diagram of a quantum dot light-emitting diode in a positive configuration according to Example 7 of the present disclosure;

FIG. 3 is a schematic structural diagram of a quantum dot light-emitting diode in an inversion configuration according to Example 10 of the present disclosure;

FIG. 4 is a flowchart of a method for preparing a composite material in a positive configuration according to Example 7 of the present disclosure.

FIG. 5 is a flowchart of a method for preparing a composite material in a positive configuration according to Example 10 of the present disclosure.

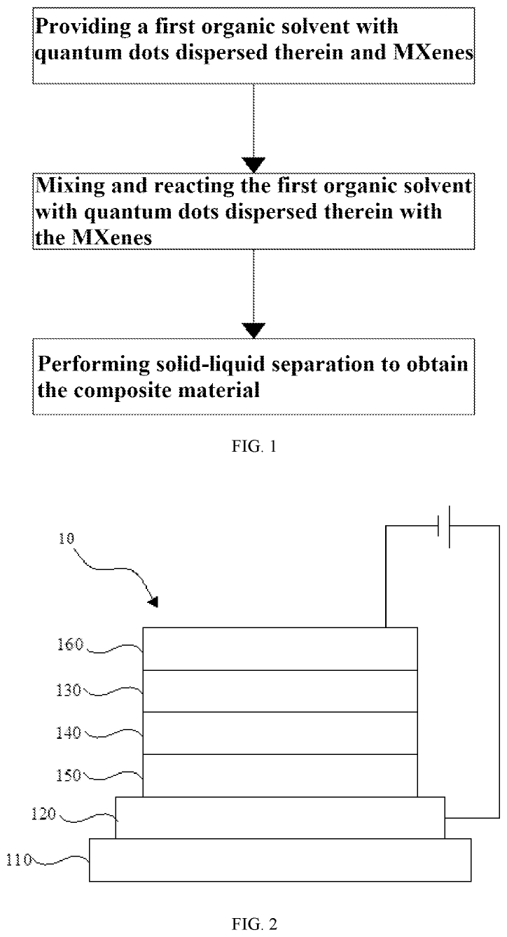

### LIST OF REFERENCE SIGNS

Quantum dot light-emitting diode—10; substrate—110; anode—120; hole transport layer—130; light-emitting layer—140; electron transport layer—150; cathode—160.

### Embodiments of Invention

Hereinafter, technical solutions in examples of the present disclosure will be clearly and completely described with reference to the accompanying drawings in examples of the present disclosure. Apparently, the described examples are only some embodiments of the present disclosure, but not all the examples of the present disclosure. All other examples that can be obtained by a person with ordinary skill in the art based on the examples in the present disclosure without creative labor belong to the protection scope of the present disclosure. In addition, it should be understood that the specific embodiments described herein are only used to illustrate and explain the present disclosure, and are not intended to limit the present disclosure.

Examples of the present disclosure provides a composite material and a preparation method therefor, and a quantum dot light-emitting diode and a preparation method therefor, which are described in detail below. It should be noted that the description order of the following examples is not taken as a limitation to the preferred order of the examples. In addition, in the description of the present disclosure, the term “including” means “including but not limited to”. Each example in the present disclosure may exist in the form of a range. It should be understood that the description in the form of a range is only for convenience and conciseness, and should not be understood as a hard limitation on the scope of the present disclosure. Accordingly, it should be considered that the range description has specifically disclosed all possible subranges and a single numerical value within the range. For example, the present disclosure provides an example in which a range value is from 20 mg/mL to 50 mg/mL, it should be considered that the description of the range from 20 mg/mL to 50 mg/mL has specifically disclosed sub-ranges, such as from 20 mg/mL to 25 mg/mL, from 30 mg/mL to 35 mg/mL, from 40 mg/mL to 45 mg/mL, from 20 mg/mL to 35 mg/mL, from 20 mg/mL to 45 mg/mL, from 40 mg/mL to 50 mg/mL, and the like, as well as single numerical values within the range, such as 20 mg/mL, 25 mg/mL, 30 mg/mL, 35 mg/mL, 40 mg/mL, 45 mg/mL, 50 mg/mL. Whenever a numerical range is given herein, it is intended to include any quotable numerical value (fractions and integers) within the indicated range, and this principle applies regardless of the range.

Examples of the present disclosure provide a composite material including quantum dots and MXenes, wherein metal atoms of the quantum dots are connected to surface groups of the MXenes through coordination bonds. The agglomeration phenomenon during the film formation process can be improved when a light-emitting layer is prepared by the composite materials, so that they have better photostability. Furthermore, when a quantum dot light-emitting diode is prepared by using the composite materials, the composite materials form fluorescence emission channels between adjacent wrinkled structures of the MXenes nanosheets after the quantum dots therein are attached to the wrinkled structures of the MXenes, so that fluorescence emitted by the quantum dots can be reflected by wrinkled walls and emitted outwardly through the fluorescence emission channels, thereby reducing the hindrance of the long-chain ligand coating on the surfaces of the existing quantum dots to the movement of carriers, and improving the quantum efficiency of the device to some extent.

“MXenes”, also known as a two-dimensional transition metal carbide, nitride or carbonitride, is a novel type of two-dimensional structural material. Its chemical general formula can be represented by Mₙ₊₁XₙT_{z}, where M refers to a transition metal, selected from Ti, Zr, Hf, V, Nb, Ta, Cr, Sc, and the like; X refers to C or/and N, and n is generally from 1 to 3, and T_{z} refers to the surface group, selected from O²⁻, OH⁻, F⁻, NH₃, NH⁴⁺, and the like.

In some embodiments, the surface groups of the MXenes are selected from one or more of hydroxyl group and halogen groups. It can be understood that MXenes can be any combination of surface group T_{z} such as hydroxyl group or halogen groups with Mₙ₊₁ and Xₙ, such as Ti₃C₂(OH)₂, Zr₃CCl₂, Ti₃C₂F₂, Mo₂CF₂, and the like. MXenes whose surface groups are hydroxyl group or halogen groups are easier to coordinate with metal atoms in the shell of quantum dots. At the same time, electrons are introduced into the light-emitting layer through the electron transport layer, and the light-emitting layer has a good carrier transport capability under the action of the MXenes quantum confinement effects. The carriers are transferred to the quantum dots through the surface groups (such as —OH, —F, or the like) of the Mₙ₊₁XₙT_{z}-type MXenes nanosheets, thereby enhancing the light-emitting efficiency of the devices and improving the performance of the quantum dot light-emitting diodes.

The constituent elements of the quantum dots include V, II-VI, IV-V or II-V elements, and the quantum dots include quantum dots with core-shell structures selected from one or more of CdSe, ZnSe, PbSe, CdTe, InP, GaN, GaP, AlP, InN, ZnTe, InAs, GaAs, CaF₂, Cd₁₋ₓZnₓS, Cd₁₋ₓZnₓSe, CdSe_{y}S_{1-y}, PbSe_{y}S_{1-y}, ZnₓCd₁₋ₓTe, CdS/ZnS, Cd₁₋ₓZnₓS/ZnS, Cd₁₋ₓZnₓSe/ZnSe, CdSe₁₋ₓSₓ/CdSe_{y}S_{1-y}/CdS, CdSe/Cd₁₋ₓZnₓSe/Cd_{y}Zn_{1-y}Se/ZnSe, Cd₁₋ₓZnₓSe/Cd_{y}Zn_{1-y}Se/ZnSe, CdS/Cd₁₋ₓZnₓS/Cd_{y}Zn_{1-y}S/ZnS, NaYF₄, NaCdF₄, Cd₁₋ₓZnₓSe_{y}S_{1-y}, CdSe/ZnS, Cd₁₋ₓZnₓSe/ZnS, CdSe/CdS/ZnS, CdSe/ZnSe/ZnS, Cd₁₋ₓZnₓSe/Cd_{y}Zn_{1-y}S/ZnS, and InP/ZnS, wherein 0≤x≤1, 0≤y≤1, and x and y are not both 0 or 1 at the same time, and x and y are fixed values. Quantum dots have excellent optical properties, including continuously adjustable full-spectrum emission peak positions, high color purity, good stability, and are excellent light-emitting and optoelectronic materials. In some examples of the present disclosure, the quantum dots may be blue quantum dots, red quantum dots, or green quantum dots. Since blue quantum dots are widely used in the light-emitting system based on quantum dots at present as light-emitting layer materials, and the method for preparing a light-emitting diode based on blue quantum dots is relatively difficult, the blue quantum dots are more valuable for reference. The blue quantum dots can be selected from CdS/ZnS, Cd₁₋ₓZnₓS, Cd₁₋ₓZnₓS/ZnS, and the like.

Optionally, the quantum dots are quantum dots with core-shell structures, and the metal atoms are shell metal atoms of the quantum dots with core-shell structures. The fluorescent properties of the quantum dots can be effectively improved by coating the shell, the quantum efficiency can be improved, and the photoelectric effect can be enhanced.

The present disclosure further provides a method for preparing composite materials including steps as follows:
Step S110: providing a first organic solvent with quantum dots dispersed therein and MXenes;
Step S120: mixing and reacting the first organic solvent with quantum dots dispersed therein with the MXenes; and
Step S130: performing solid-liquid separation to obtain the composite materials.

In the step S120, the mixing and reacting include mixing the first organic solvent with quantum dots dispersed therein with MXenes, and stirring. Stirring enables the quantum dots to react more fully with the MXenes and increases the yield of the composite materials MXenes-quantum dots. Stirring includes mechanical stirring, magnetic stirring, and the like. In some examples, stirring may be replaced by other operations with similar effects, such as ultrasound, vortex, and the like.

In the step S130, the composite materials refer to the solid precipitates obtained after solid-liquid separation. Step S130 specifically includes: cooling the reacted solution to room temperature, precipitating with a second organic solvent, or collecting the precipitate by means of centrifugation. The second organic solvent is selected from one or more of ethyl acetate, acetone and ethanol. Precipitating with the second organic solvent is achieved by using the solubility of the second organic solvent in the reactant. The precipitation of the composite materials is achieved by using good solvent and bad solvent, and the solvent used in the previous stage is removed, so that the products are collected. It can be understood that the second organic solvent may be used alone or in combination. In addition, the process of treating with the second organic solvent may be repeated to realize purification of the products, for example, treating with ethyl acetate+ethanol first, followed by treatingt with acetone+ethanol.

The molar ratio of quantum dots to MXenes is 1:(0.05 to 0.5). It can be understood that the molar ratio of quantum dots to MXenes may be any value within the range 1:(0.05 to 0.5), such as 1:0.05, 1:0.1, 1:0.2, 1:0.3, 1:0.4, 1:0.5, and the like. Under the condition that the molar ratio of quantum dots to MXenes is 1:(0.05 to 0.5), MXenes and quantum dots are combined in the obtained composite materials to improve the carrier efficiency of quantum dots. Further, the composite materials prepared under this condition are dispersed in a solvent, so that the light-emitting layer film obtained from the composite materials is relatively flat and smooth, thereby improving the performance of the device. Further, the molar ratio of quantum dots to MXenes is 1:(0.1 to 0.3). When the molar ratio of quantum dots to MXenes is less than 1:0.1, the recombination amount of MXenes with quantum dots is small, and the effect on improving the carrier efficiency of the quantum dots is not obvious. When the molar ratio of quantum dots to MXenes is greater than 1:0.3, dispersion of the prepared MXenes-quantum dots in the solvent decreases, thereby affecting the device performance.

The first organic solvent is an alkene or alkane with a boiling point ranging from 280° C. to 400° C., with a boiling point within this range, volatilization can be avoided under the conditions of realizing the reaction. In addition, the quantum dots are well dissolved in olefin or alkane. It can be understood that the first organic solvent may be an alkene or alkane with a boiling point ranging from 280° C. to 400° C., such as 1-octadecene (ODE), 1-hexadecene, 1-eicosene, and the like. This kind of solvent has low price, strong stability, and good dispersion performance for quantum dots.

In some embodiments, the concentration of quantum dots in the first organic solvent ranges from 20 mg/mL to 50 mg/mL, it can be understood that the concentration of quantum dots in the first organic solvent may be any value within the range from 20 mg/mL to 50 mg/mL, such as 20 mg/mL, 25 mg/mL, 30 mg/mL, 35 mg/mL, 40 mg/mL, 45 mg/mL, 50 mg/mL, and the like. Further, the concentration of quantum dots in the first organic solvent ranges from 20 mg/mL to 30 mg/mL. Within this concentration range, the quantum dots are not easy to agglomerate in the solvent, so that better dispersion effect can be obtained, and the best contact area can be obtained during ligand-exchange reaction, which is not easy to cause excessive grafting of ligands, so that the light-emitting layer prepared from the obtained composite materials has good performance. If the concentration of quantum dots is too low, it is easy to cause excessive dispersion in the solvent, and excessive spacing between particles will lead to excessive grafting of ligands, which affects the performance of the light-emitting layer. At the same time, if the concentration of quantum dots is too high, it is easy to form agglomerates, which affects the good contact between quantum dots and ligands.

In some embodiments, the step S120 may be carried out at a temperature ranging from 200° C. to 250° C. under a protective gas. It can be understood that the temperature may be any value within the range from 200° C. to 250° C., such as 200° C., 205° C., 210° C., 215° C., 220° C., 225° C., 230° C., 235° C., 240° C., 245° C., 250° C., and the like. Further, the temperature ranges from 200° C. to 220° C. This temperature range enables sufficient reaction of MXenes with quantum dots. The protective gas may be selected from argon (Ar) gas, nitrogen (N₂) gas, and the like. When the reaction is carried out under a protective gas atmosphere, unnecessary reactions such as oxidation can be effectively avoided, and purity of the obtained reaction products is higher.

It should be noted that the MXenes used to prepare the composite materials can be purchased from existing commercial products or prepared from MAX phase materials. In order to better understand the present disclosure, the present disclosure provides a method for preparing MXenes, which includes steps as follows:
Step S210: immersing the MAX phase materials in an active treatment solution at a temperature ranging from 80° C. to 100° C. for a time period of from 7 h to 10 h; and
Step S220: filtering to obtain MXenes materials.

The active treatment solution is selected from one or more of hydrofluoric acid, a mixture of hydrochloric acid, fluoride, etc., and an alkaline solution. The active treatment solution can be used to extract A-position element (for example, an Al atom) which has a weak binding force in the MAX phase materials to obtain the MXenes materials. The active treatment solution can also provide T_{z} group in MXenes. For example, Ti₃C₂F₂, Zr₃C₂F₂ and other MXenes materials whose surface group T_{z} is —F can be prepared by immersing in a hydrofluoric acid active treatment solution. Ti₃C₂(OH)₂, Zr₃C₂(OH)₂ and other MXenes materials whose surface group T_{z} is —OH can be prepared by firstly immersing in a hydrofluoric acid active treatment solution and then immersing in an alkaline active solution. These materials can be better used in subsequent experiments.

In the step S210, the temperature of the active treatment solution ranges from 80° C. to 100° C., and further, the temperature of the active treatment solution ranges from 95° C. to 100° C. It should be noted that the active treatment solution can be heated to 80-100° C., or an active treatment solution with a temperature of 80-100° C. can be provided.

A washing step may also be included between step S210 and step S220: washing the MXenes samples with deionized water until the pH value of the solution is between 6 and 7.

After the step S220, a drying step may also be included: heating and drying under vacuum condition at 95-105° C. for 20-25 h. It can be understood that heating and drying under vacuum condition can be carried out at any value within the temperature range from 95° C. to 105° C., such as 95° C., 96° C., 97° C., 98° C., 99° C., 100° C., 101° C., 102° C., 103° C., 104° C., 105° C., and the like. Under these conditions, the solvent can be sufficiently dried to obtain dried MXenes materials for subsequent experiments. It should be noted that the temperature can be heated to 95-105° C., or a vacuum heating environment of 95-105° C. can be provided.

A MAX phase material may be represented by a basic formula M(n+1)AXn, wherein M represents a transition metal element, for example, Ti, Zr, Hf, V, Nb, Ta, Cr, Sc, and the like may be selected. A represents a main group element, for example, Al, Zn, Si, Ga, and the like may be selected; and X represents carbon or nitrogen. This kind of materials can also be obtained by using commercially available MAX phase materials, or obtained by preparation. In order to better understand the present disclosure, the present disclosure provides a method for preparing MAX phase materials, which includes:
Step S310: mixing a first powder, a second powder and a third powder in a molar ratio ranging from 3:(1 to 2):(1 to 2); and
Step S320: calcining at 650-750° C. for 1 hour to 2 hours to obtain MAX phase materials. The first powder is a metal powder M selecting from one or more of Ti, Zr, Hf, V, Nb, Ta, Cr, Sc. The second powder is a metal powder A selecting from one or more of Al, Zn, Si, Ga. The third powder is a carbon source X, such as graphite.

In some embodiments, the molar ratio of the first powder to the second powder to the third powder is 3:(1 to 2):(1 to 2), it can be understood that the molar ratio of the first powder to the second powder to the third powder may be any value within the range of 3:(1 to 2):(1 to 2), such as 3:1.1:1, 3:1.2:2, 3:1.3:1, 3:1.4:2, 3:1.5:1, 3:1.6:2, 3:1.7:1, 3:1.8:2, 3:1.9:1, 3:2:2, and the like. Further, the molar ratio of the first powder to the second powder to the third powder is 3:(1.2 to 1.7):(1.5 to 2). Within this molar ratio range, sufficiently reacted MAX phase materials can be prepared, and impurity compounds are not easily formed, thus reducing the difficulty in impurity removal. The MAX phase materials prepared in this molar ratio range is capable of converting the metal powder A into T_{z} in an appropriate amount during the further preparation of MXenes. The obtained MAX phase materials can be used as raw materials subsequently for preparing a composite material, a quantum dot light-emitting diode, and the like, so that a subsequent experiment can achieve better effects. For example, the composite materials prepared by using this kind of MAX phase materials as raw materials can obtain a compact and dense film in the preparation of a quantum dot light-emitting diode, and particles on the surface of the film are evenly distributed, thereby effectively improving the photoelectric performance of the quantum dot light-emitting diode. The molar ratio of the first powder, the second powder, and the third powder is selected to be 3:(1 to 2):(1 to 2), which can make the carbon sources participating in the reaction appropriate, so that the ratio of carbon sources, metal powders M and metal powders A is appropriate, so as to avoid the formation of the impurity compounds that are not easily removed due to excessive carbon source, and further to prevent metal powders M and metal powders A from affecting the production of MAX phase materials. Further, the molar ratio of the first powder to the second powder is controlled to be 3:(1 to 2), so that the amount of metal powders A in the subsequent reaction is sufficient to ensure that the amount of metal powders A converted to T_{z} in the process of preparing the MXenes by the MAX phase materials is sufficient. At the same time, it can avoid the condition that metal powders A cannot be completely converted into T_{z} in the subsequent reaction, and excessive metal powders A will remain as impurities.

In the step S320, calcining is carried out at 650-750° C. for 1 hour to 2 hours. It can be understood that calcining is carried out at any value within the temperature range 650-750° C., for example, 650° C., 660° C., 670° C., 680° C., 690° C., 700° C., 710° C., 720° C., 730° C., 740° C., 750° C., and the like. Further, calcining is carried out at 650-700° C. Calcining in this temperature range is not easy to sintering and can fully react. It should be noted that the temperature can be heated to 650-750° C., or a calcining environment of 650-750° C. can be provided. Further, calcining is carried out for 1 hour to 2 hours. Further, calcining is carried out for 1 hour to 1.5 hours. It should be noted that this step can be carried out by any equipment in the art that can achieve this condition, such as a tube furnace or the like. In some embodiments, the calcination process may be carried out in a protective gas atmosphere, such as argon (Ar) gas, nitrogen (N₂) gas, and the like. When the reaction is carried out in a protective gas atmosphere, unnecessary reactions such as oxidation can be effectively avoided, and purity of reaction products is higher.

A ball-milling step may also be included between step S310 and step S320: carrying out ball-milling for a time period of 45 hours to 50 hours. The grinding medium of the ball-milling can be made of materials commonly used in the field, including one or more of agate, zirconia, stainless steel, quenched and tempered steel, hard tungsten carbide, silicon nitride or sintered corundum. Ball-milling is carried out for a time period of 45 hours to 50 hours, it can be understood that the time for carrying out ball-milling may be any value within the time range 45-50 h, such as 45 h, 46 h, 47 h, 48, 49 h, 50 h, or the like. Within this time range, the materials can be crushed by the grinding body, so that the powders of the three materials M, A, and X are more uniform in texture, and can be mixed more fully during this process.

A tableting step may also be included between the ball-milling step and step S320: pressing at 0.8-1.2 MPa to obtain compressed tablets. The shape of the compressed tablets is not limited, for example, it can be circular. This procedure facilitates subsequent experimental operations.

After the step S320, a grinding step may also be included: grinding the MAX phase materials to obtain MAX phase material powders.

On the basis of the above examples, the present disclosure also provides a quantum dot light-emitting diode including the composite materials described in any one of the above examples. Specifically, the quantum dot light-emitting diode includes an anode, a hole transport layer, a light-emitting layer, an electron transport layer, and a cathode disposed in a stacked manner. The materials of the light-emitting layer include composite materials.

The composite materials include quantum dots and MXenes, and metal atoms of the quantum dots are connected to surface groups of the MXenes through coordination bonds.

In some embodiments, the quantum dot light-emitting diode further includes a substrate. The materials of the substrate are not explicitly limited, and the fabrication of flexible devices may be accomplished by using a hard glass substrate, or a flexible PET substrate.

The hole transport layer may be made of conventional hole transport materials in the art, such as poly(9,9-dioctylfluorene-co-n-(4-butylphenyl)diphenylamine) (TFB), polyvinylcarbazole (PVK), polytriphenylamine (Poly-TPD), tris (4-(9-carbazolyl)phenyl)amine (TCTA), 4,4′-N,N′-dicarbazole biphenyl (CBP), poly(3,4-ethylenedioxythiophene)/polystyrene sulfonate (PEDOT:PSS), or a mixture of any combination thereof, or may be other hole transport materials with high performance.

The light-emitting layer may be made of the above-mentioned composite material MXenes-quantum dots. When a quantum dot light-emitting diode is prepared by using a light-emitting layer based on the composite materials, fluorescence emission channels are formed by wrinkled structures of the MXenes nanosheets, so that fluorescence emitted by the quantum dots attached on the MXenes can be emitted outwardly through the fluorescence emission channels, which can improve the quantum efficiency of the device to some extent. At the same time, electrons are introduced into the light-emitting layer through the electron transport layer, and the light-emitting layer has a good carrier transport capability under the action of the MXenes quantum confinement effect. The carriers are transferred to the quantum dots through the surface groups (—OH, —F) of the Mₙ₊₁XₙT_{z}-type MXenes nanosheets, thereby enhancing the light-emitting efficiency of the devices and improving the performance of the quantum dot light-emitting diodes.

The electron transport layer may be made of conventional hole transport materials in the art, such as zinc oxide (ZnO), calcium (Ca), barium (Ba), cesium fluoride (CsF), lithium fluoride (LiF), cesium carbonate (CsCO₃), and aluminum 8-hydroxyquinoline (Alq3), and the like.

In some embodiments, the quantum dot light-emitting diode may be in a positive configuration, in which the anode is disposed close to the substrate. Materials of the anode may be doped metal oxides, such as indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), aluminum-doped magnesium oxide (AMO), and the like, or may be a composite electrode in which metals are sandwiched between doped or onn-doped transparent metal oxides, such as AZO/Ag/AZO, AZO/Al/AZO, ITO/Ag/ITO, ITO/Al/ITO, ZnO/Ag/ZnO, ZnO/Al/ZnO, TiO2/Ag/TiO2, TiO2/Al/TiO2, ZnS/Ag/ZnS, ZnS/Al/ZnS, and the like. Materials of the cathode may be metals or alloy, such as silver (Ag), aluminum (Al), gold (Au), or the like.

In some embodiments, the quantum dot light-emitting diode may also be in an inversion configuration, in which the cathode is disposed close to the substrate. Materials of the cathode may be doped metal oxides, such as indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), magnesium-doped zinc oxide (MZO), aluminum-doped magnesium oxide (AMO), and the like, or may be a composite electrode in which a metal is sandwiched between doped or undoped transparent metal oxides, such as AZO/Ag/AZO, AZO/Al/AZO, ITO/Ag/ITO, ITO/Al/ITO, ZnO/Ag/ZnO, ZnO/Al/ZnO, TiO2/Ag/TiO2, TiO2/Al/TiO2, ZnS/Ag/ZnS, ZnS/Al/ZnS, and the like. Materials of the anode may be metals or alloy, such as silver (Ag), aluminum (Al), gold (Au), or the like.

It should be noted that in addition to the above layers, the quantum dot light-emitting diode provided in the present disclosure may be additionally provided with a plurality of functional layers that contribute to improving the performance of the quantum dot light-emitting diodes, including an electron injection layer, a hole injection layer, and the like.

Materials of each layer of the quantum dot light-emitting diode provided in the present disclosure may be conventional materials in the art, but are not limited to the range of materials set forth in the examples.

In order to better understand the present disclosure, the present disclosure further provides a method for preparing a quantum dot light-emitting diode, which includes steps as follows:
Step S410: providing a solution in which the composite materials are dissolved in a solvent, wherein the solvent is alkane non-polar solvent;
Step S420: depositing the solution on an electron transport layer to form a light-emitting layer; or
depositing the solution on a hole transport layer to form a light-emitting layer.

The composite materials include quantum dots and MXenes, and metal atoms of the quantum dots are connected to surface groups of the MXenes through coordination bonds.

A solution in which the composite materials are dissolved in a solvent is provided, wherein the non-polar solvent is selected from one or more of non-polar solvents such as n-hexane, n-octane, n-decane, chloroform and ODE. Further, the solvent is an alkane non-polar solvent, the composite materials can be well dispersed in an alkane non-polar solvent, and can be used for storage and subsequent operations.

In some embodiments, in the step S420, said “depositing the solution” includes spin-coating the prepared solution containing composite materials with a certain concentration onto a substrate that is placed on a homogenizer to form a film, and drying at an appropriate temperature, wherein the substrate is coated with a hole transport layer or an electron transport layer. The thickness of the light-emitting layer is controlled by adjusting the concentration of the solution, the spin-coating speed, and the spin-coating time, and the thickness of the light-emitting layer ranges from about 20 nm to about 60 nm. It can be understood that the thickness of the light-emitting layer may be any value within the range from 20 nm to 60 nm, for example, 20 nm, 25 nm, 30 nm, 35 nm, 40 nm, 45 nm, 50 nm, 55 nm, 60 nm, and the like. Within this thickness range of the light-emitting layer, agglomeration and hole defects are not easy to occur, and the prepared quantum dot light-emitting diode has good performance. It can be understood that, in addition to spin-coating, the method for preparing the light-emitting layer in the present disclosure may also be realized by other ways with the same or similar effects, including solution processing, such as spraying, doctor-coating, or the like, to deposit the composite materials onto the hole transport layer or the electron transport layer.

The preparation method of each layer in the quantum dot light-emitting diode can be realized by conventional techniques in the art. Deposition includes chemical methods and physical methods. The chemical methods can be selected from chemical vapor deposition, a successive ionic layer absorption and reaction, anodic oxidation, electrolytic deposition, and co-precipitation. The physical methods include physical coating and solution processing. A specific physical coating method may be selected from thermal evaporation deposition, electron beam evaporation, magnetron sputtering, multi-arc ion plating, physical vapor deposition, atomic layer deposition, pulsed laser deposition, and the like. The solution processing method may be selected from spin-coating, printing, ink jet printing, scrape coating, dip-coating, soaking, spraying, roller-coating, casting, slot die coating, strip coating, and the like. Specific processing methods and processing conditions are all common methods in the art.

In some embodiments, a method of preparing a quantum dot light-emitting diode in a positive configuration may further include a step S411 of depositing a hole transport layer on an ITO substrate between step S410 and step S420. Specifically, a prepared solution containing hole transport materials can be spin-coated onto the ITO substrate that is placed on a homogenizer to form a film. The film thickness is controlled by adjusting the concentration of the solution, the spin-coating speed, and the spin-coating time. Then thermal annealing is carried out at an appropriate temperature. After the step S420, the method may further include a step S431 of depositing an electron transport layer on the light-emitting layer. Said “depositing an electron transport layer” is carried out by placing the substrate that has been spin-coated with a light-emitting layer in a vacuum evaporation chamber and evaporating an electron transport layer with a thickness of about 80 nm at an evaporation rate of about 0.01-0.5 nm/s. After the step S431, the method may further include a step S441 of depositing a cathode on the electron transport layer. Said “depositing a cathode” is carried out by placing the substrate on which each functional layer has been deposited in an evaporation chamber and thermally evaporating a layer of metallic silver or aluminum with a thickness of 15-30 nm through a mask plate as the cathode, or a nano-Ag wire or Cu wire can be used, which has low resistance and enables carriers to be injected smoothly.

In some embodiments, a method of preparing a quantum dot light-emitting diode in an inversion configuration may further include a step S412 of depositing an electron transport layer on an ITO substrate between step S410 and step S420. Said “depositing an electron transport layer” is carried out by placing the ITO substrate in a vacuum evaporation chamber and evaporating an electron transport layer with a thickness of about 80 nm at an evaporation rate of about 0.01-0.5 nm/s. After the step S420, the method may further include a step S432 of depositing a hole transport layer on the light-emitting layer. Said “depositing a hole transport layer” is carried out by spin-coating the prepared solution containing hole transport materials onto the substrate that is placed on a homogenizer to form a film, wherein the substrate is coated with a light-emitting layer. The film thickness is controlled by adjusting the concentration of the solution, the spin-coating speed, and the spin-coating time. Then thermal annealing is carried out at an appropriate temperature. After the step S432, the method may further include a step S442 of depositing an anode on the hole transport layer. Said “depositing an anode” is carried out by placing the substrate on which each functional layer has been deposited in an evaporation chamber and thermally evaporating a layer of metallic silver or aluminum with a thickness of 15-30 nm through a mask plate as the anode, or a nano-Ag wire or Cu wire can be used, which has low resistance and enables carriers to be injected smoothly.

In some embodiments, after the step S441 or step S442, the method may further include a S450 of encapsulating the quantum dot light-emitting diode. Said “encapsulating” may be realized by commonly used machines or manually. In some embodiments, encapsulation is accomplished under the environmental conditions that both the oxygen content and the water content are lower than 0.1 ppm to ensure stability of the devices.

In order to better understand the solutions, specific Examples 1-12 and Comparative Examples 1-3 are provided herein to further illustrate the solutions in detail.

### Example 1

This example provides a method for preparing a composite material including steps as follows:

(1) Mixing titanium (Ti) powders, aluminum (Al) powders and graphite in a molar ratio of 3:1.5:2. After 48 h of ball-milling, small discs were obtained by pressing at a high pressure of 1 MPa. Then placing the small discs in a tube furnace, introducing argon (Ar) gas, and calcining at 700° C. for 1 hour. Followed by taking out the small discs, cooling to room temperature and grinding them into powders for later use, thereby obtaining MAX phase materials Ti₃AlCl₂.

(2) Immersing Ti₃AlCl₂ in hydrofluoric acid at a temperature of 100° C. for 10 hours, thus the Al layer was removed to realize fluorination treatment. After the fluorination treatment, washing MXenes with deionized water until pH of the solution is between 6 and 7. Finally, filtering the MXenes solution and drying under vacuum at 100° C. for 24 hours to obtain MXenes materials Ti₃C₂F₂. The chemical reaction formulas involved are as follows: Ti₃AlCl₂+3HF═AlF₃+3/2H₂+Ti₃C₂, and Ti₃C₂+2HF=Ti₃C₂F₂+H₂.

(3) Dispersing CdS/ZnS in 20 mL of 1-octadecene (ODE) under argon atmosphere at 200° C., followed by mixing and stirring with Ti₃C₂F₂ materials for 30 minutes to obtain a reaction solution, wherein the concentration of CdS/ZnS in 1-octadecene (ODE) was 20 mg/mL and the molar ratio of CdS/ZnS to Ti₃C₂F₂ was 1:0.1. After the reaction was completed, cooling the reaction solution to room temperature, and taking 10 mL of the reaction solution to carry out a first precipitation by using 20 mL of ethyl acetate+10 mL of ethanol, followed by centrifuging and dissolving in n-hexane. Then carrying out a second precipitation with 10 mL of acetone+10 mL of ethanol, followed by centrifuging to obtain composite materials Ti₃C₂F₂-CdS/ZnS. A solution of the composite materials Ti₃C₂F₂—CdS/ZnS can be obtained by subsequently re-dispersing the composite materials Ti₃C₂F₂—CdS/ZnS in n-hexane.

### Example 2

This example provides a method for preparing a composite material including steps as follows:

(1) Mixing Ti powders, Al powders and graphite in a molar ratio of 3:1.3:2. After 48 h of ball-milling, small discs were obtained by pressing at a high pressure of 1 MPa. Then placing the small discs in a tube furnace, introducing argon gas, and calcining at 650° C. for 1.5 hours.

Followed by taking out the small discs, cooling to room temperature and grinding them into powders for later use, thereby obtaining Ti₃AlCl₂ materials.

(2) Immersing Ti₃AlCl₂ in hydrofluoric acid at a temperature of 100° C. for 5 hours to remove the Al layer, and then carrying out alkalization treatment with 5% NaOH for 2 hours to obtain MXenes that are rich in OH groups, so as to realize alkalization activity treatment. After that, washing MXenes with deionized water until pH of the solution is between 6 and 7. Finally, filtering the MXenes solution and drying under vacuum at 100° C. for 24 hours to obtain Ti₃C₂(OH)₂ materials. The chemical reaction formulas involved are as follows: Ti₃AlCl₂+3HF═AlF₃+3/2H₂+Ti₃C₂, Ti₃C₂+2HF=Ti₃C₂F₂+H₂, and Ti₃C₂F₂+2NaOH═Ti₃C₂(OH)₂+2NaF.

(3) Dispersing Cd₁₋ₓZnₓS in 20 mL of 1-hexadecene under argon atmosphere at 200° C., followed by mixing and stirring with Ti₃C₂(OH)₂ materials for 1 hour to obtain a reaction solution, wherein the concentration of Cd₁₋ₓZnₓS in 1-hexadecene was 30 mg/mL and the molar ratio of Cd₁₋ₓZnₓS to Ti₃C₂(OH)₂ was 1:0.2. After the reaction was completed, cooling the reaction solution to room temperature, and taking 10 mL of the reaction solution to carry out a first precipitation by using 20 mL of ethyl acetate+10 mL of ethanol, followed by centrifuging and dissolving in n-hexane. Then carrying out a second precipitation with 10 mL of acetone+10 mL of ethanol, followed by centrifuging to obtain composite materials Ti₃C₂(OH)₂—Cd₁₋ₓZnₓS. A solution of the composite materials Ti₃C₂(OH)₂—Cd₁₋ₓZnₓS can be obtained by subsequently re-dispersing the composite materials Ti₃C₂(OH)₂—Cd₁₋ₓZnₓS in n-hexane.

### Example 3

This example provides a method for preparing a composite material including steps as follows:

(1) Mixing zirconium (Zr) powders, Al powders and graphite in a molar ratio of 3:1.2:2. After 48 h of ball-milling, small discs were obtained by pressing at a high pressure of 1 MPa. Then placing the small discs in a tube furnace, introducing argon gas, and calcining at 700° C. for 1 hour. Followed by taking out the small discs, cooling to room temperature and grinding them into powders for later use, thereby obtaining Zr₃AlCl₂ materials.

(2) Immersing Zr₃AlCl₂ materials in hydrofluoric acid at a temperature of 100° C. for 10 hours, thus the Al layer was removed to realize fluorination treatment. After the fluorination treatment, washing MXenes samples with deionized water until pH of the solution is between 6 and 7. Finally, filtering the MXenes solution and drying under vacuum at 100° C. for 24 hours to obtain Zr₃C₂F₂ materials. The chemical reaction formulas involved are as follows: Zr₃AlCl₂+3HF═AlF₃+3/2H₂+Zr₃C₂, and Ti₃C₂+2HF=Zr₃C₂F₂+H₂.

(3) Dispersing Cd₁₋ₓZnₓS/ZnS in 20 mL of ODE under argon atmosphere at 200° C., followed by mixing and stirring with Zr₃C₂F₂ materials for 30 minutes to obtain a reaction solution, wherein the concentration of Cd₁₋ₓZnₓS/ZnS in ODE was 20 mg/mL and the molar ratio of Cd₁₋ₓZnₓS/ZnS to Zr₃C₂F₂ was 1:0.3. After the reaction was completed, cooling the reaction solution to room temperature, and taking 10 mL of the reaction solution to carry out a first precipitation by using 20 mL of ethyl acetate+10 mL of ethanol, followed by centrifuging and dissolving in n-hexane. Then carrying out a second precipitation with 10 mL of acetone+10 mL of ethanol, followed by centrifuging to obtain composite materials Zr₃C₂F₂—Cd₁₋ₓZnₓS/ZnS. A solution of the composite materials Zr₃C₂F₂—Cd₁₋ₓZnₓS/ZnS can be obtained by subsequently re-dispersing the composite materials Zr₃C₂F₂—Cd₁₋ₓZnₓS/ZnS in n-hexane.

### Example 4

This example provides a method for preparing a composite material including steps as follows:

(1) Mixing titanium (Ti) powders, aluminum (Al) powders and graphite in a molar ratio of 3:1.5:1.2. After 48 h of ball-milling, small discs were obtained by pressing at a high pressure of 1 MPa. Then placing the small discs in a tube furnace, introducing argon (Ar) gas, and calcining at 700° C. for 1.5 hours. Followed by taking out the small discs, cooling to room temperature and grinding them into powders for later use, thereby obtaining MAX phase materials Ti₃AlCl₂.

(2) Immersing Ti₃AlCl₂ in hydrofluoric acid at a temperature of 100° C. for 10 hours, thus the Al layer was removed to realize fluorination treatment. After the fluorination treatment, washing MXenes with deionized water until pH of the solution is between 6 and 7. Finally, filtering the MXenes solution and drying under vacuum at 100° C. for 24 hours to obtain MXenes materials Ti₃C₂F₂. The chemical reaction formulas involved are as follows: Ti₃AlCl₂+3HF═AlF₃+3/2H₂+Ti₃C₂, and Ti₃C₂+2HF=Ti₃C₂F₂+H₂.

(3) Dispersing CdS/ZnS in 20 mL of 1-octadecene (ODE) under argon atmosphere at 200° C., followed by mixing and stirring with Ti₃C₂F₂ materials for 30 minutes to obtain a reaction solution, wherein the concentration of CdS/ZnS in 1-octadecene (ODE) was 48 mg/mL and the molar ratio of CdS/ZnS to Ti₃C₂F₂ was 1:0.1. After the reaction was completed, cooling the reaction solution to room temperature, and taking 10 mL of the reaction solution to carry out a first precipitation by using 20 mL of ethyl acetate+10 mL of ethanol, followed by centrifuging and dissolving in n-hexane. Then carrying out a second precipitation with 10 mL of acetone+10 mL of ethanol, followed by centrifuging to obtain composite materials Ti₃C₂F₂—CdS/ZnS. A solution of the composite materials Ti₃C₂F₂—CdS/ZnS can be obtained by subsequently re-dispersing the composite materials Ti₃C₂F₂—CdS/ZnS in n-hexane.

### Example 5

This example provides a method for preparing a composite material including steps as follows:

(1) Mixing Ti powders, Al powders and graphite in a molar ratio of 3:1.3:2. After 48 h of ball-milling, small discs were obtained by pressing at a high pressure of 1 MPa. Then placing the small discs in a tube furnace, introducing argon gas, and calcining at 650° C. for 1.5 hours. Followed by taking out the small discs, cooling to room temperature and grinding them into powders for later use, thereby obtaining Ti₃AlCl₂ materials.

(2) Immersing Ti₃AlCl₂ in hydrofluoric acid at a temperature of 80° C. for 5 hours to remove the Al layer, and then carrying out alkalization treatment with 5% NaOH for 2 hours to obtain MXenes that are rich in OH groups, so as to realize alkalization activity treatment. After that, washing MXenes with deionized water until pH of the solution is between 6 and 7. Finally, filtering the MXenes solution and drying under vacuum at 100° C. for 24 hours to obtain Ti₃C₂(OH)₂ materials. The chemical reaction formulas involved are as follows: Ti₃AlCl₂+3HF═AlF₃+3/2H₂+Ti₃C₂, Ti₃C₂+2HF=Ti₃C₂F₂+H₂, and Ti₃C₂F₂+2NaOH═Ti₃C₂(OH)₂+2NaF.

(3) Dispersing Cd₁₋ₓZnₓS in 20 mL of 1-eicosene under argon atmosphere at 250° C., followed by mixing and stirring with Ti₃C₂(OH)₂ materials for 1 hour to obtain a reaction solution, wherein the concentration of Cd₁₋ₓZnₓS in 1-eicosene was 30 mg/mL and the molar ratio of Cd₁₋ₓZnₓS to Ti₃C₂(OH)₂ was 1:0.05. After the reaction was completed, cooling the reaction solution to room temperature, and taking 10 mL of the reaction solution to carry out a first precipitation by using 20 mL of ethyl acetate+10 mL of ethanol, followed by centrifuging and dissolving in n-hexane. Then carrying out a second precipitation with 10 mL of acetone+10 mL of ethanol, followed by centrifuging to obtain composite materials Ti₃C₂(OH)₂—Cd₁₋ₓZnₓS. A solution of the composite materials Ti₃C₂(OH)₂—Cd₁₋ₓZnₓS can be obtained by subsequently re-dispersing the composite materials Ti₃C₂(OH)₂—Cd₁₋ₓZnₓS in n-hexane.

### Example 6

This example provides a method for preparing a composite material including steps as follows:

(1) Mixing zirconium (Zr) powders, Al powders and graphite in a molar ratio of 3:2:2. After 48 h of ball-milling, small discs were obtained by pressing at a high pressure of 1 MPa. Then placing the small discs in a tube furnace, introducing argon gas, and calcining at 700° C. for 1 hour. Followed by taking out the small discs, cooling to room temperature and grinding them into powders for later use, thereby obtaining Zr₃AlCl₂ materials.

(2) Immersing Zr₃AlCl₂ materials in hydrofluoric acid at a temperature of 100° C. for 10 hours, thus the Al layer was removed to realize fluorination treatment. After the fluorination treatment, washing MXenes samples with deionized water until pH of the solution is between 6 and 7. Finally, filtering the MXenes solution and drying under vacuum at 100° C. for 24 hours to obtain Zr₃C₂F₂ materials. The chemical reaction formulas involved are as follows: Zr₃AlCl₂+3HF═AlF₃+3/2H₂+Zr₃C₂, and Ti₃C₂+2HF=Zr₃C₂F₂+H₂.

(3) Dispersing Cd₁₋ₓZnₓS/ZnS in 20 mL of ODE under argon atmosphere at 200° C., followed by mixing and stirring with Zr₃C₂F₂ materials for 30 minutes to obtain a reaction solution, wherein the concentration of Cd₁₋ₓZnₓS/ZnS in ODE was 35 mg/mL and the molar ratio of Cd₁₋ₓZnₓS/ZnS to Zr₃C₂F₂ was 1:0.5. After the reaction was completed, cooling the reaction solution to room temperature, and taking 10 mL of the reaction solution to carry out a first precipitation by using 20 mL of ethyl acetate+10 mL of ethanol, followed by centrifuging and dissolving in n-hexane. Then carrying out a second precipitation with 10 mL of acetone+10 mL of ethanol, followed by centrifuging to obtain composite materials Zr₃C₂F₂—Cd₁₋ₓZnₓS/ZnS. A solution of the composite materials Zr₃C₂F₂—Cd₁₋ₓZnₓS/ZnS can be obtained by subsequently re-dispersing the composite materials Zr₃C₂F₂—Cd₁₋ₓZnₓS/ZnS in n-hexane.

### Example 7

Referring to FIG. 2, this example provides a quantum dot light-emitting diode in a positive configuration. The quantum dot light-emitting diode includes a substrate 110, an anode 120, a hole transport layer 130, a light-emitting layer 140, an electron transport layer 150, and a cathode 160 that are stacked. A material of the substrate 110 is a glass sheet, a material of the anode 120 is an ITO substrate, a material of the hole transport layer 130 is TFB, a material of the electron transport layer 150 is ZnO, a material of the light-emitting layer 140 is a composite material Ti₃C₂F₂—CdS/ZnS, and a material of the cathode 160 is Al.

This example further provides a method for preparing a quantum dot light-emitting diode in a positive configuration. Referring to FIG. 4, the method includes steps as follows:
providing a solution of composite materials Ti₃C₂F₂—CdS/ZnS;
depositing a hole transport layer on an ITO substrate;
depositing the solution of composite materials Ti₃C₂F₂—CdS/ZnS on the hole transport layer to form a light-emitting layer;
depositing an electron transport layer on the light-emitting layer; and
depositing a cathode on the electron transport layer to obtain a quantum dot light-emitting diode.

### Example 8

This example provides a quantum dot light-emitting diode, which includes a substrate, an anode, a hole transport layer, a light-emitting layer, an electron transport layer, and a cathode that are stacked. A material of the substrate is a glass sheet, a material of the anode is an ITO substrate, a material of the hole transport layer is TFB, a material of the electron transport layer is ZnO, a material of the light-emitting layer is a composite material Ti₃C₂(OH)₂—Cd₁₋ₓZnₓS, and a material of the cathode is Al.

This example further provides a method for preparing a quantum dot light-emitting diode, which includes steps as follows:
providing a solution of composite materials Ti₃C₂(OH)₂—Cd₁₋ₓZnₓS;
depositing a hole transport layer on an ITO substrate;
depositing the solution of composite materials Ti₃C₂(OH)₂—Cd₁₋ₓZnₓS on the hole transport layer to form a light-emitting layer;
depositing an electron transport layer on the light-emitting layer; and
depositing a cathode on the electron transport layer to obtain a quantum dot light-emitting diode.

### Example 9

This example provides a quantum dot light-emitting diode, which includes a substrate, an anode, a hole transport layer, a light-emitting layer, an electron transport layer, and a cathode that are stacked. A material of the substrate is a glass sheet, a material of the anode is an ITO substrate, a material of the hole transport layer is TFB, a material of the electron transport layer is ZnO, a material of the light-emitting layer is a composite material Zr₃C₂F₂—Cd₁₋ₓZnₓS/ZnS, and a material of the cathode is Al.

This example further provides a method for preparing a quantum dot light-emitting diode, which includes steps as follows:
providing a solution of composite materials Zr₃C₂F₂—Cd₁₋ₓZnₓS/ZnS;
depositing a hole transport layer on an ITO substrate;
depositing the solution of Zr₃C₂F₂—Cd₁₋ₓZnₓS/ZnS on the hole transport layer to form a light-emitting layer;
depositing an electron transport layer on the light-emitting layer; and
depositing a cathode on the electron transport layer to obtain a quantum dot light-emitting diode.

### Example 10

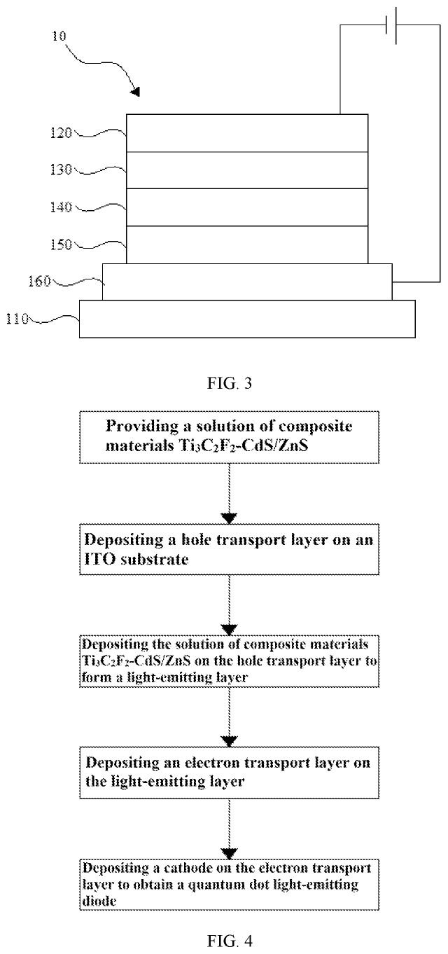

Referring to FIG. 3, this example provides a quantum dot light-emitting diode in an inversion configuration. The quantum dot light-emitting diode includes an anode 120, a hole transport layer 130, a light-emitting layer 140, an electron transport layer 150, a cathode 160, and a substrate 110 that are stacked. A material of the substrate 110 is a glass sheet, a material of the cathode 160 is an ITO substrate, a material of the hole transport layer 130 is TFB, a material of the electron transport layer 150 is ZnO, a material of the light-emitting layer 140 is a composite material Ti₃C₂F₂—CdS/ZnS, and a material of the anode is Al.

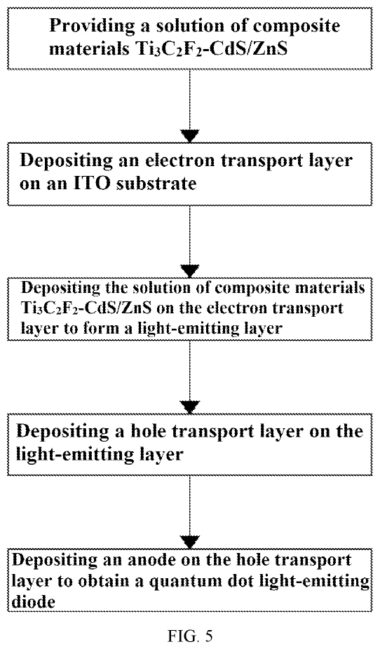

This example further provides a method for preparing a quantum dot light-emitting diode. Referring to FIG. 5, the method includes steps as follows:
providing a solution of composite materials Ti₃C₂F₂—CdS/ZnS;
depositing an electron transport layer on an ITO substrate;
depositing the solution of composite materials Ti₃C₂F₂—CdS/ZnS on the electron transport layer to form a light-emitting layer;
depositing a hole transport layer on the light-emitting layer; and
depositing an anode on the hole transport layer to obtain a quantum dot light-emitting diode.

### Example 11

This example provides a quantum dot light-emitting diode, which includes an anode, a hole transport layer, a light-emitting layer, an electron transport layer, a cathode, and a substrate that are stacked. A material of the substrate is a glass sheet, a material of the cathode is an ITO substrate, a material of the hole transport layer is TFB, a material of the electron transport layer is ZnO, a material of the light-emitting layer is a composite material Ti₃C₂(OH)₂—Cd₁₋ₓZnₓS, and a material of the anode is Al.

This example further provides a method for preparing a quantum dot light-emitting diode, which includes steps as follows:
providing a solution of composite materials Ti₃C₂(OH)₂—Cd₁₋ₓZnₓS;
depositing an electron transport layer on an ITO substrate;
depositing a Ti₃C₂(OH)₂—Cd₁₋ₓZnₓS solution on the electron transport layer to form a light-emitting layer;
depositing a hole transport layer on the light-emitting layer; and
depositing an anode on the hole transport layer to obtain a quantum dot light-emitting diode.

### Example 12

This example provides a quantum dot light-emitting diode, which includes an anode, a hole transport layer, a light-emitting layer, an electron transport layer, a cathode, and a substrate that are stacked. A material of the substrate is a glass sheet, a material of the cathode is an ITO substrate, a material of the hole transport layer is TFB, a material of the electron transport layer is ZnO, a material of the light-emitting layer is a composite material Zr₃C₂F₂—Cd₁₋ₓZnₓS/ZnS, and a material of the anode is Al.

This example further provides a method for preparing a quantum dot light-emitting diode, which includes steps as follows:
providing a solution of composite materials Zr₃C₂F₂—Cd₁₋ₓZnₓS/ZnS;
depositing an electron transport layer on an ITO substrate;
depositing the solution of composite materials Zr₃C₂F₂—Cd₁₋ₓZnₓS/ZnS on the electron transport layer to form a light-emitting layer;
depositing a hole transport layer on the light-emitting layer; and
depositing an anode on the hole transport layer to obtain a quantum dot light-emitting diode.

### Comparative Example 1

A quantum dot light-emitting diode, which includes an anode, a hole transport layer, a light-emitting layer, an electron transport layer, a cathode, and a substrate that are stacked. A material of the substrate is a glass sheet, a material of the cathode is an ITO substrate, a material of the hole transport layer is TFB, a material of the electron transport layer is ZnO, a material of the light-emitting layer is CdS/ZnS quantum dots, and a material of the anode is Al.

### Comparative Example 2

A quantum dot light-emitting diode, which includes an anode, a hole transport layer, a light-emitting layer, an electron transport layer, a cathode, and a substrate that are stacked. A material of the substrate is a glass sheet, a material of the cathode is an ITO substrate, a material of the hole transport layer is TFB, a material of the electron transport layer is ZnO, a material of the light-emitting layer is Cd₁₋ₓZnₓS quantum dots, and a material of the anode is Al.

### Comparative Example 3

A quantum dot light-emitting diode, which includes an anode, a hole transport layer, a light-emitting layer, an electron transport layer, a cathode, and a substrate that are stacked. A material of the substrate is a glass sheet, a material of the cathode is an ITO substrate, a material of the hole transport layer is TFB, a material of the electron transport layer is ZnO, a material of the light-emitting layer is Cd₁₋ₓZnₓS/ZnS quantum dots, and a material of the anode is Al.

In order to illustrate the changes in performance of the quantum dot light-emitting diodes prepared by using the composite materials MXenes-quantum dots in the present disclosure, the external quantum efficiency (EQE) of Examples 7-12 and Comparative Examples 1-3 were investigated, respectively. The external quantum efficiency of the quantum dot light-emitting diodes was measured by using an EQE optical testing instrument. The quantum dot light-emitting diodes have a structure of anode/hole transport layer/light-emitting layer/electron transport layer/cathode, or a structure of cathode/electron transport layer/light-emitting layer/hole transport layer/anode. The test results are shown in Table 1 below:

TABLE 1

| Groups | External quantum efficiency (EQE)/(%) |
|---|---|
| Comparative Example 1 | 3.19 |
| Comparative Example 2 | 3.69 |
| Comparative Example 3 | 4.34 |
| Example 7 | 8.26 |
| Example 8 | 7.48 |
| Example 9 | 6.17 |
| Example 10 | 6.49 |
| Example 11 | 5.26 |
| Example 12 | 5.14 |

As can be seen from Table 1 above, the external quantum efficiencies of the quantum dot light-emitting diodes (materials of the light-emitting layer are composite materials MXenes-quantum dots) provided in Example 7-12 of the present disclosure are significantly higher than those of the quantum dot light-emitting diodes (materials of the light-emitting layer are quantum dots) provided in Comparative Example 1-3, indicating that the quantum dot light-emitting diodes prepared by using the composite materials MXenes-quantum dot as the light-emitting layer material have better light-emitting efficiency.

In view of above, MXenes-quantum dots can be prepared efficiently by the method for preparing a composite material according to examples of the present disclosure. Since the quantum dots in the composite materials are attached to the two-dimensional MXenes nanosheets, it is possible to improve the agglomeration phenomenon during the film formation process when a light-emitting layer is prepared by the composite materials, so that they have better photostability. Furthermore, when a quantum dot light-emitting diode is prepared by using a light-emitting layer based on the composite materials, the composite materials form fluorescence emission channels between adjacent wrinkled structures of the MXenes nanosheets after the quantum dots are attached to the wrinkled structures of the MXenes, so that fluorescence emitted by the quantum dots can be reflected by wrinkled walls and emitted outwardly through the fluorescence emission channels, which can improve the quantum efficiency of the device to some extent. At the same time, electrons are introduced into the light-emitting layer through the electron transport layer, and the light-emitting layer has a good carrier transport capability under the action of the MXenes quantum confinement effect. The carriers are transferred to the quantum dots through the surface groups (—OH, —F) of the Mₙ₊₁XₙT_{z}-type MXenes nanosheets, thereby enhancing the light-emitting efficiency of the device and improving the performance of the quantum dot light-emitting diode.

In view of above, the composite material and the preparation method therefor, and the quantum dot light-emitting diode and the preparation method therefor provided in examples of the present disclosure have been described in detail. Specific examples are used to illustrate the principles and embodiments of the present disclosure. The description of the above examples is merely provided to help understand the method of the present disclosure and the core idea thereof Δt the same time, those ordinarily skilled in the art may make changes in both the specific embodiments and application scope in accordance with the ideas of the present disclosure. In view of the foregoing, the content of the specification should not be construed as limiting the present disclosure.

1. A composite material comprising quantum dots and MXenes, wherein metal atoms of the quantum dots are connected to surface groups of the MXenes through coordination bonds.

2. The composite material according to claim 1, wherein the surface group of the MXenes is selected from one or more of hydroxyl group and halogen groups.

3. The composite material according to claim 1, wherein the quantum dots are selected from one or more of CdSe, ZnSe, PbSe, CdTe, InP, GaN, GaP, AlP, InN, ZnTe, InAs, GaAs, CaF₂, Cd₁₋ₓZnₓS, Cd₁₋ₓZnₓSe, CdSe_{y}S_{1-y}, PbSe_{y}S_{1-y}, ZnₓCd₁₋ₓTe, CdS/ZnS, Cd₁₋ₓZnₓS/ZnS, Cd₁₋ₓZnₓSe/ZnSe, CdSe₁₋ₓSₓ/CdSe_{y}Si_{1-y}/CdS, CdSe/Cd₁₋ₓZnₓSe/Cd_{y}Zn_{1-y}Se/ZnSe, Cd₁₋ₓZnₓSe/Cd_{y}Zn_{1-y}Se/ZnSe, CdS/Cd₁₋ₓZnₓS/Cd_{y}Zn_{1-y}S/ZnS, NaYF₄, NaCdF₄, Cd₁₋ₓZnₓSe_{y}Si_{1-y}, CdSe/ZnS, Cd₁₋ₓZnₓSe/ZnS, CdSe/CdS/ZnS, CdSe/ZnSe/ZnS, Cd₁₋ₓZnₓSe/Cd_{y}Zn_{1-y}S/ZnS, and InP/ZnS; and
wherein, 0≤x≤1, 0≤y≤1, and x and y are not both 0 or 1 at the same time.

4. The composite material according to claim 1, wherein the quantum dots are quantum dots with core-shell structures, and the metal atom is a shell metal atom of the quantum dots with core-shell structures.

5. A method for preparing a composite material, comprising:
providing a first organic solvent with quantum dots dispersed therein and MXenes;
mixing and reacting the first organic solvent with quantum dots dispersed therein with the MXenes; and
performing solid-liquid separation to obtain the composite material.

6. The method according to claim 5, wherein a molar ratio of the quantum dots to the MXenes is 1:(0.05 to 0.5).

7. The method according to claim 5, wherein a molar ratio of the quantum dots to the MXenes is 1:(0.1 to 0.3).

8. The method according to claim 5, wherein the first organic solvent is an alkene or an alkane with a boiling point ranging from 280° C. to 400° C.

9. The method according to claim 5, wherein a concentration of the quantum dots in the first organic solvent ranges from 20 mg/mL to 50 mg/mL.

10. The method according to claim 5, wherein the mixing and reacting is carried out at a temperature ranging from 200° C. to 250° C. under a protective gas.

11. The method according to claim 5, wherein the mixing and reacting is carried out for a time period of from 0.5 h to 1 h.

12. The method according to claim 5, wherein the surface group of the MXenes is selected from one or more of hydroxyl group and halogen groups.

13. The method according to claim 5, wherein the quantum dots are selected from one or more of CdSe, ZnSe, PbSe, CdTe, InP, GaN, GaP, AlP, InN, ZnTe, InAs, GaAs, CaF₂, Cd₁₋ₓZnₓS, Cd₁₋ₓZnₓSe, CdSe_{y}S_{1-y}, PbSe_{y}S_{1-y}, ZnₓCd₁₋ₓTe, CdS/ZnS, Cd₁₋ₓZnₓS/ZnS, Cd₁₋ₓZnₓSe/ZnSe, CdSe₁₋ₓSₓ/CdSe_{y}S_{1-y}/CdS, CdSe/Cd₁₋ₓZnₓSe/Cd_{y}Zn_{1-y}Se/ZnSe, Cd₁₋ₓZnₓSe/Cd_{y}Zn_{1-y}Se/ZnSe, CdS/Cd₁₋ₓZnₓS/Cd_{y}Zn_{1-y}S/ZnS, NaYF₄, NaCdF₄, Cd₁₋ₓZnₓSe_{y}S_{1-y}, CdSe/ZnS, Cd₁₋ₓZnₓSe/ZnS, CdSe/CdS/ZnS, CdSe/ZnSe/ZnS, Cd₁₋ₓZnₓSe/Cd_{y}Zn_{1-y}S/ZnS, and InP/ZnS; and
wherein, 0≤x≤1, 0≤y≤1, and x and y are not both 0 or 1 at the same time.

14. The method according to claim 5, wherein the quantum dots are quantum dots with core-shell structures, and the metal atom is a shell metal atom of the quantum dots with core-shell structures.

15. A quantum dot light-emitting diode comprising an anode, a hole transport layer, a light-emitting layer, an electron transport layer, and a cathode that are stacked;
wherein a material of the light-emitting layer comprises the composite material according to claim 1.

16. The quantum dot light-emitting diode according to claim 15, wherein the quantum dot light-emitting diode further comprises a substrate on which the cathode or the anode is disposed.

17. The quantum dot light-emitting diode according to claim 15, wherein the surface group of the MXenes is selected from one or more of hydroxyl group and halogen groups.

18. The quantum dot light-emitting diode according to claim 15, wherein the quantum dots are selected from one or more of CdSe, ZnSe, PbSe, CdTe, InP, GaN, GaP, AlP, InN, ZnTe, InAs, GaAs, CaF₂, Cd₁₋ₓZnₓS, Cd₁₋ₓZnₓSe, CdSe_{y}S_{1-y}, PbSe_{y}S_{1-y}, ZnₓCd₁₋ₓTe, CdS/ZnS, Cd₁₋ₓZnₓS/ZnS, Cd₁₋ₓZnₓSe/ZnSe, CdSe₁₋ₓSₓ/CdSe_{y}S_{1-y}/CdS, CdSe/Cd₁₋ₓZnₓSe/Cd_{y}Zn_{1-y}Se/ZnSe, Cd₁₋ₓZnₓSe/Cd_{y}Zn_{1-y}Se/ZnSe, CdS/Cd₁₋ₓZnₓS/Cd_{y}Zn_{1-y}S/ZnS, NaYF₄, NaCdF₄, Cd₁₋ₓZnₓSe_{y}Si_{1-y}, CdSe/ZnS, Cd₁₋ₓZnₓSe/ZnS, CdSe/CdS/ZnS, CdSe/ZnSe/ZnS, Cd₁₋ₓZnₓSe/Cd_{y}Zn_{1-y}S/ZnS, and InP/ZnS; and
wherein, 0≤x≤1, 0≤y≤1, and x and y are not both 0 or 1 at the same time.

19. The quantum dot light-emitting diode according to claim 15, wherein the quantum dots are quantum dots with core-shell structures, and the metal atom is a shell metal atom of the quantum dots with core-shell structures.

20. A method for preparing a quantum dot light-emitting diode, comprising:
providing a solution in which a composite material is dissolved in a solvent, and the solvent being an alkane non-polar solvent;
depositing the solution on an electron transport layer to form a light-emitting layer; or
depositing the solution on a hole transport layer to form a light-emitting layer;
wherein the composite material comprises quantum dots and MXenes, and a metal atom of the quantum dots is connected to a surface group of the MXenes through a coordination bond.
